(19) United States
(12) Patent Application Publication
(10) Pub. No.: US 2006/0240668 A1
(43) Pub. Date: Oct. 26, 2006

(54) Semiconductor device with metallic electrodes and a method for use in forming such a device

(76) Inventor: John Christopher Rudin, Bristol (GB)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/564,862

(22) PCT Filed: Jul. 9, 2004
(86) PCT No.: PCT/GB04/02999

§ 371 Date: Jun. 16, 2006

(30) Foreign Application Priority Data
Jul. 12, 2003 (GB) 03163920

(51) Int. Cl. H01L 21/44; H01L 29/76; H01L 29/94; H01L 31/00

(52) U.S. Cl. 438/678; 257/372

(57) ABSTRACT

A semiconductor device comprising: a first electrode component; a second electrode component; a first layer comprising at least a portion of the first electrode component and at least a portion of the second electrode component; a second layer having a portion comprising deposited semiconductor material contacting the first and second electrode components; and a third layer comprising a substrate, wherein the first, second and third layers are arranged in order such that the second layer is positioned between the first layer and the third layer and wherein the first and second electrode components comprise electro-deposited metal. A method for use in forming a layered semiconductor device comprising: forming a transfer layer on a conductive carrier by the deposition of insulating material on the conductive carrier and then the electro-deposition of metal onto at least first and second portions of the conductive carrier, selectively exposed through the insulating material, to form first and second metal portions; fixing the transfer layer to a substrate portion of the device; and removing the conductive carrier from the device.

### FIELD OF THE INVENTION

Embodiments of the invention relate to semiconductor devices with one or more metallic electrodes and methods for forming such devices. Some embodiments relate to transistor devices that are suitable for integration in large area substrates at low cost.

### BACKGROUND TO THE INVENTION

JP63299296 (Meiko), JP63299297A (Meiko) and “Manufacturing of Printed Wiring Boards by Ultra-high Speed Electroforming” by Norio Kawachi (Meiko) et al, Printed Circuit World Convention, June 1990 describe the use of the electroforming technique in creating circuit boards (printed wiring boards). Electroforming is an additive process that involves obtaining a replica of a metal carrier by electrolytic deposition of a metallic film using the carrier as a cathode. A patterned photo-resist is used to limit the electro-deposition of material to the exposed areas of the cathode. The documents additionally teach a transfer lamination process in which the deposited metal and photo-resist are laminated to a substrate and the master is removed leaving a deposited metal photo-resist substrate combination. JP63299296 (Meiko), JP63299297A (Meiko) additionally disclose the electrolytic deposition of a copper plate layer on the master before the deposition of the metal. This copper layer is transferred in the transfer-lamination process and is removed by etching.

U.S. Pat. No. 6,284,072 discloses the formation of patterning on a conductive carrier by micro-moulding. An insulating material is embossed to create a pattern that limits the electro-deposition of metal to exposed areas of the conductive carrier.

Electroforming is used in the semiconductor industry in the creation of printed wiring boards and large scale interconnects on bulk semiconductors. Electroforming is not accurate enough for use in bulk semiconductor device processing which is at a scale of nanometres.

The bulk semiconductor industry typically uses metal sputtering with UV photo-lithography to define small scale metal interconnects.

Organic semiconductors are a fairly recent development compared with bulk semiconductors. Devices made from organic semiconductors cannot match the speed or efficiencies of bulk semiconductors, but they have other distinct advantages. They are suitable for large area processing and can be used on flexible substrates. They have therefore attracted a lot of attention for their potential application in display device technologies, particularly their use in thin film transistors for use in active matrix displays.

An organic transistor typically has metallic source, gate and drain electrodes. A thin film of organic semiconductor forms a channel interconnecting the source and drain electrodes, that is separated from the gate electrode by a thin dielectric layer.

As years of research into the creation of bulk semiconductors have been carried out, the organic transistors presently re-use technology developed for bulk semiconductors as these processes are well understood. For example, the metallic electrodes are typically created by metal sputtering.

The inventors have realised that the use of sputtering may be optimal for bulk semiconductors but is sub-optimal for low cost, large area integrated circuits, such as displays incorporating organic thin film transistors.

Sputtering requires a vacuum environment. This is expensive and difficult to implement for large area processes.

Also, to obtain low impedance interconnects using sputtering the interconnects must either be wide or thick. A thick interconnect can create stresses which require controlling, which adds cost. Thick interconnects may limit the resolution of the devices (the number per unit area).

U.S. Pat. No. 6,344,662 describes the creation of a TFT having a hybrid organic-inorganic semiconductor layer. The gate metallization is formed using electron beam evaporation and the metal source and drain are formed separately by vapor deposition. Claim 6 states, without further explanation or clarification, that the gate electrode is produced by a process selected from the group consisting of evaporation, sputtering, chemical vapor deposition, electrodeposition, spin coating, and electroless plating

### BRIEF DESCRIPTION OF THE INVENTION

It would therefore be desirable to provide an improved method for creating a semiconductor device suitable for integration in large area substrates at low cost.

Some embodiments of the invention provide a semiconductor device comprising: a first electrode component; a second electrode component; a first layer comprising at least a portion of the first electrode component and at least a portion of the second electrode component; a second layer having a portion comprising deposited semiconductor material contacting the first and second electrode components; and a third layer comprising a substrate, wherein the first, second and third layers are arranged in order such that the second layer is positioned between the first layer and the third layer and wherein the first and second electrode components comprise electro-deposited metal.

Some embodiments of the invention provide a method for use in forming a transistor device including a source electrode, a drain electrode and a gate electrode comprising: electro-depositing metal to form at least a portion of the gate electrode; electro-depositing metal to form simultaneously at least portions of the source electrode and the drain electrode; depositing semiconductor material; transferring at least the source electrode and drain electrode to a substrate to create the transistor device.

Some embodiments of the invention provide a method for use in forming a layered semiconductor device comprising: forming a transfer layer on a conductive carrier by the deposition of insulating material on the conductive carrier and then the electro-deposition of metal onto at least first and second portions of the conductive carrier, selectively exposed through the insulating material, to form first and second metal portions; fixing the transfer layer to a substrate portion of the device; and removing the conductive carrier from the device.

The terms electro-deposition and electrolytic deposition are synonymous.

### BRIEF DESCRIPTION OF THE DRAWINGS

For a better understanding of the invention and to understand how it may be brought into effect reference will now be made to the accompanying drawings of example embodiments of the invention in which:

FIGS. 1A to 1H illustrate stages in forming a substrate portion 134 according to embodiment A;

FIGS. 2A to 2C illustrate stages in forming a source/drain transfer layer 136 on a carrier 202 according to embodiment A; and

FIGS. 3A to 3B illustrate stages in the transfer of the source/drain transfer layer 136 to the substrate portion 134 to form the TFT 140 according to embodiment A;

FIGS. 4A to 4H illustrate stages in the process of forming a transistor device 340 according to embodiment B; and

FIG. 5 illustrates the transistor device 340 according to embodiment B.

### DETAILED DESCRIPTION OF EMBODIMENTS OF THE INVENTION

### Embodiment A

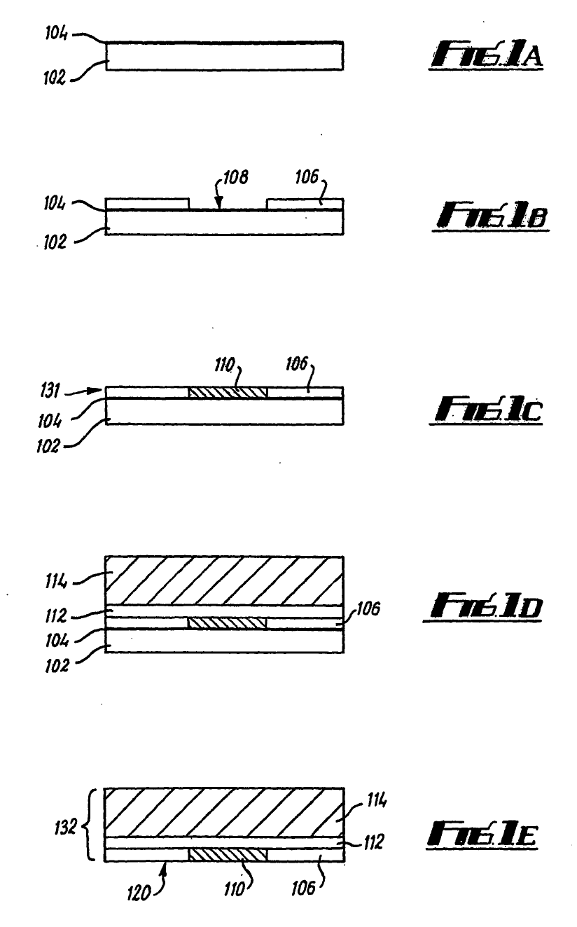

FIGS. 1A to 1H, 2A to 2C and 3A to 3B schematically illustrate stages during an additive method for forming a layered active semiconductor device using successive electrolytic deposition and transfer lamination steps. The figures are not to scale.

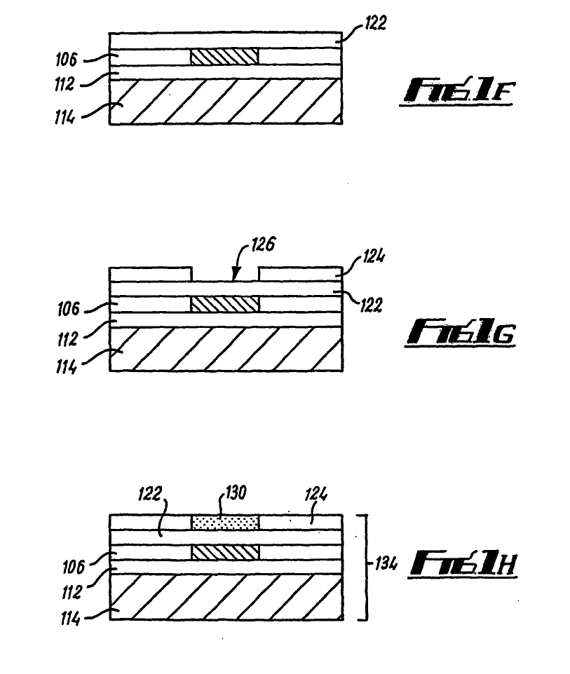

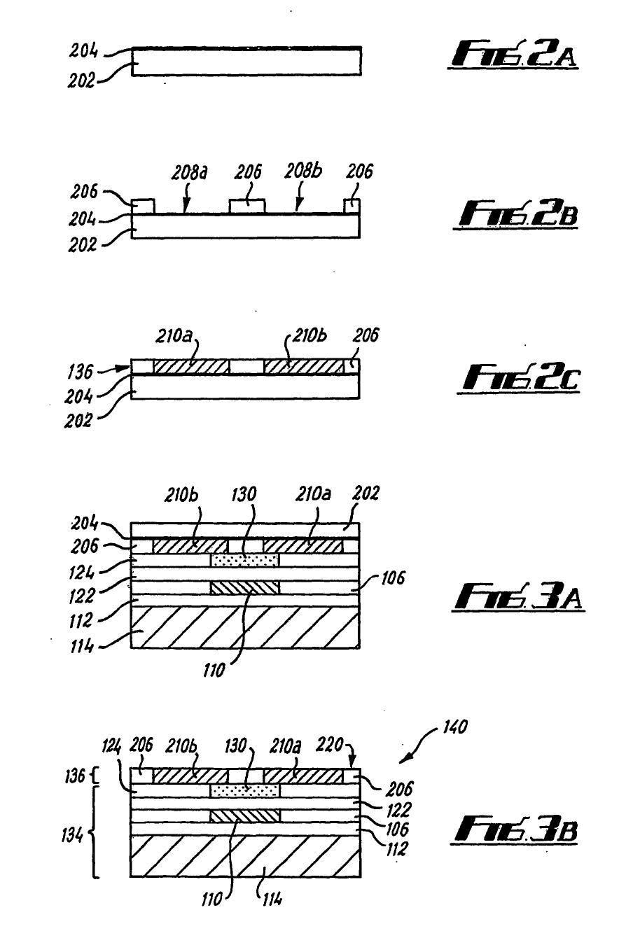

A substrate portion 134, including a base portion 132, is formed in the stages illustrated in FIGS. 1A to 1H. A source/drain transfer layer 136 on a carrier 202 is formed in the stages illustrated in FIGS. 2A to 2C. The source/drain transfer layer 136 is transferred from the carrier 202 to the substrate portion 134 in the stages illustrated in FIGS. 3A to 3B. The final semiconductor device 140, an organic thin film transistor (TFT), is illustrated in FIG. 3B.

Forming the Substrate Portion (FIGS. 1A to 1H)

FIGS. 1A to 1E illustrate the creation of a base 132 of the substrate portion 134 by electrolytic deposition, followed by transfer lamination.

FIG. 1A illustrates a passivated substantially planar conductive carrier 102. This may be a platen or a sheet of material in a roll to roll process. The passivated substantially planar conductive carrier 102 includes a passivation layer 104 this may for example include a very thin oxide and/or a surfactant.

FIGS. 1B and 1C illustrate the formation of a gate transfer layer 131 on the conductive carrier 102. In FIG. 1B insulating material 106 is selectively formed on the passivated conductive carrier 102 by a selective additive process or a selective subtractive process. In a selective subtractive process, insulating material is deposited over the whole of the passivated conductive carrier 102 as a substantially planar layer and selectively removed from a portion 108 of the passivated conductive carrier 102. In a selective additive process, insulating material is deposited only in the regions of the passivated conductive carrier 102 where required to form patterned structures 106. This may be achieved, for example, by embossing, micro-molding, photolithography or any other suitable alternative process. If photolithography is used, the insulating material 106 is preferably photo-patternable. It is selectively exposed to radiation through a mask and developed to expose the portion 108 of the conductive carrier 102. One suitable photo-patternable insulator is SU-8 by Micro-Chemical Corporation, which is a hard UV cure polymer, which is used at a thickness of between 1 and 5 μm.

Metal is then deposited by electrolytic deposition on the exposed portion 108 of the conductive carrier 102, which is connected as a cathode, to form metal portion 110. This metal portion 110 will form the gate of the final TFT. The metal may be any metal that is capable of electrolytic deposition with good conductivity e.g. Ni, Cu, Ag, Au. It is typically deposited with a thickness of between 2 and 5 μm to substantially the same thickness as the insulating material 106.

The gate transfer layer 131 is adhered to a passive substrate 114 using a layer of adhesive 112 as illustrated in FIG. 1D. This substrate will form the substrate of the final TFT. The substrate 114 may be made of glass or it may be a flexible plastic substrate, for example, made from PET. The adhesive used may be NOA81 by Norland Products Inc. The thickness of the substrate 114 is typically between 50 and 200 um. The thickness of the adhesive layer 112 is typically between 5 and 20 um.

The passivated conductive carrier 102 is then removed to form the base 132 of the substrate portion, as illustrated in FIG. 1E. In more detail, the adhesive layer 112 is cured using ultra-violet (UV) radiation or applied heat. The structure may then be shock-cooled and the passivated carrier 102 peeled off. The base 132 of the substrate portion has an upper substantially planar surface 120 including an upper substantially planar surface of the metal portion 110 as shown in the Figure.

The substrate portion 134 is then built up from this base 132 as illustrated in FIGS. 1F to 1H.

In FIG. 1F, a dielectric layer 122 is formed over the whole of the upper surface 120 of the base 132. It overlies the layer 131 that includes insulating material 106 and metal 110. This dielectric layer 122 forms the gate dielectric of the final TFT. The dielectric layer may be formed from SU8 and typically has a thickness of the order 100 nm.

In FIG. 1G, adhesive electrically-insulating material 124 is selectively formed over the dielectric layer 122 in order to create a well 126. This can be achieved by depositing the adhesive insulating material uniformly over the dielectric layer and selectively removing the adhesive insulating layer from over the metal material 110 to form the well 126. An effective mechanism for doing this is to use a photo-patternable material as the insulating adhesive material, exposing it through the substrate 114, adhesive layer 112, insulating material 106 and dielectric layer 122 and then developing it. The metal portion 110 acts as a self-aligned mask for this photolithographic process. A suitable insulating adhesive material is NOA81, which is typically applied to a thickness of a few microns.

In FIG. 1H semiconductor material is deposited into the well 126 to fill it and thereby form a semiconductor portion 130. The semiconductor may be an organic semiconductor, a solution processable semiconductor, nano-particulate dispersion of semiconductor; conjugated polymers or oligomers in solution. The semiconductor may be deposited by spinning it on in liquid solvent form and evaporating the solvent. Alternatively micro-dispensing techniques such as piezo inkjet or thermal inkjet may be used to selectively fill the well or trench 126. Further laser, heat or radiation processes may be used to improve the semiconductor properties. This completes the formation of the substrate portion 134.

Forming a Source/Drain Transfer Layer

FIGS. 2A to 2C illustrate stages during the creation of a source/drain transfer layer 136 on a conductive carrier 202 by electrolytic deposition.

FIG. 2A illustrates a passivated substantially planar conductive carrier 202. This may be a platen or a sheet of material in a roll to roll process. The passivated substantially planar conductive carrier 202 includes a passivation layer 204 this may for example include a very thin oxide and/or a surfactant.

FIGS. 2B and 2C illustrate the formation of a source/drain transfer layer 136 on the conductive carrier 202. In FIG. 2B an insulating material 206 is selectively formed on the passivated conductive carrier 202. This can be achieved by depositing the insulating material over the whole of the passivated conductive carrier 202 as a substantially planar layer and selectively removing the insulating material from portions 208a and 208b of the passivated conductive carrier 202. This may be achieved by embossing or photolithography. If photolithography is used, the insulating material 206 is photo-patternable. It is exposed to radiation through a mask and developed to expose the portions 208a and 208b of the conductive carrier 202. One suitable photo-patternable insulator is SU-8 by Micro-Chemical Corporation, which is a hard UV cure polymer, which is used at a thickness of between 1 and 5 μm.

Metal is then deposited by electrolytic deposition on the exposed portions 208a and 208b of the conductive carrier 202, which is connected as a cathode, to form metal portions 210a and 210b. The metal portions 210a and 210b will form the source and drain of the final TFT. The metal may be any metal that is capable of electrolytic deposition with good conductivity e.g. Ni, Cu, Ag, Au. It is typically deposited with a thickness of between 1 and 5 μm to substantially the same thickness as the insulating material 206.

The source/drain transfer layer 136 on the passivated conductive carrier 202 is illustrated in FIG. 2C.

Transfer Source/Drain Transfer Layer 136 onto Substrate Portion 134

The source/drain transfer layer 136 is then transferred to the substrate portion 134 by a transfer lamination process as illustrated in FIGS. 3A and 3B.

In FIG. 3A, the source/drain transfer layer 136 is adhered to the substrate portion 134 using the adhesive insulating layer 124. The semiconductor portion 130 is overlaid by the source/drain transfer layer 136 and makes physical connection with the metal portions 208a and 208b. This embeds the semiconductor portion 130 within the device 140.

The adhesive layer 124 is cured using ultra-violet (UV) radiation or applied heat. The structure may then be shock-cooled and the passivated conductive carrier 202 is then removed (peeled-off) to form the TFT device 140, as illustrated in FIG. 3B. The TFT device 140 has an upper substantially planar surface 220 including the upper substantially planar surfaces of the metal portions 210a and 210b.

The TFT device 140 has a first layer including an electrolytically deposited metal source 210a and an electrolytically deposited metal drain 210b; a second layer of insulating adhesive material 124 forming a well containing deposited semiconductor material that forms a semiconductor portion 130, contacts the source 210a and drain 210b and forms the channel of the device; a third layer including a passive substrate 114; a fourth substantially planar layer including an electrolytically deposited metal gate 110 and insulator 106; a fifth substantially planar continuous dielectric layer 122. Portions of the source 210a and drain 210b overlap the gate 110 but are separated therefrom by the semiconductor material 130 and dielectric layer 122. The gate 110 and the semiconductor material 130 are aligned.

The substrate 114 may be a large area substrate (many square centimetres or metres) with thousands or millions of devices 140 integrated thereon.

It should be appreciated that the above-described method has a number of advantages. The method uses a small number of masks and the associated problem of their accurate alignment is limited. The above-described processes can be carried out at low temperature (room temp +/−100 degrees Celsius) and without vacuum processing. A further advantage is that the semiconductor material is encapsulated within the device, rendering it robust and reducing susceptibility to any contamination/chemical attack from subsequent processing. The resulting upper surface of the device is substantially planar which is also advantageous for further processing, particularly in display applications.

### Embodiment B

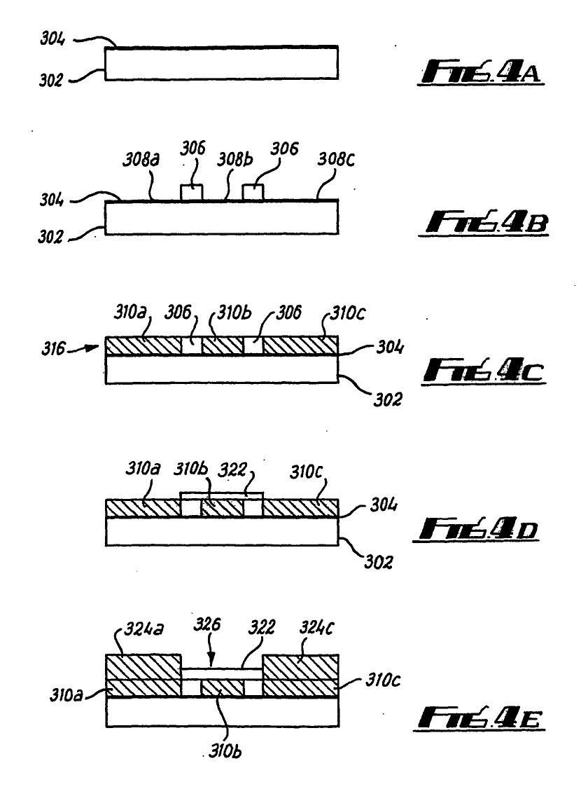

FIGS. 4A to 4H schematically illustrate stages during an additive method for forming a layered thin film transistor (TFT) device 340 using electrolytic deposition and transfer lamination. The figures are not to scale.

FIG. 4A illustrates a passivated substantially planar conductive carrier 302. This may be a platen or a sheet of material in a roll to roll process. The passivated substantially planar conductive carrier 302 includes a passivation layer 304 this may for example include a very thin oxide and/or a surfactant.

FIGS. 4B and 4C illustrate the formation of a first layer 316 of the transistor device 340 on the conductive carrier 302. In FIG. 4B insulating material 306 is selectively formed on the passivated conductive carrier 302 by a selective additive process or a selective subtractive process. In a selective subtractive process, insulating material is deposited over the whole of the passivated conductive carrier 302 as a substantially planar layer and selectively removed from first, second and third portions 308a, 308b and 308c of the passivated conductive carrier 302. In a selective additive process, insulating material is deposited only in the regions of the passivated conductive carrier 302 where required to form patterned structures 306. This may be achieved by, for example, embossing, micro-molding, photolithography or any other suitable alternative process. If photolithography is used, the insulating material 306 is photo-patternable. It is exposed to radiation through a mask or using a spot-laser and developed to expose the portions 308a, 308b and 308c of the conductive carrier 302. One suitable photo-patternable insulator is SU-8 by Micro-Chemical Corporation. This is a hard UV cure polymer, which is used at a thickness of between 1 and 5 μm.

The conductive carrier 302 is connected as a cathode and metal is deposited by electrolytic deposition on the first, second and third exposed portions 308a, 308b and 308c of the passivated conductive carrier 302 to form respective first, second and third metal portions 310a, 310b and 310c. The first metal portion 310a will eventually form part of the drain of the transistor device 340. The second metal portion 310b will eventually form the gate of the transistor device 340. The third metal portion 310c will eventually form part of the source of the transistor device 340.

The metal may be any metal that is capable of electrolytic deposition with good conductivity e.g. Ni, Cu, Ag, Au. It is typically deposited with a thickness of between 2 and 5 μm to substantially the same thickness as the insulator material 306.

In FIG. 4D, dielectric material 322 is selectively formed. It covers the second metal portion 310b and overlaps the portions of the insulating layer 306 that separate the second metal portion 310b from the first metal portion 310a and from the third metal portion 310c. The dielectric material 322 may be formed from a photo-patternable material, such as SU8, which is deposited over the whole of the first layer 316 and laser spot cured in the area where it is to remain. Development of the resist removes it to form the dielectric material 322 covering the second metal portion 310b. The overlap of the dielectric material 322 with the portions of the insulating layer 306, provides tolerance in the alignment of the laser.

The dielectric material 322 therefore covers the second metal portion 310b. This masks the second metal portion 310b from further electrolytic deposition. The dielectric material 322 forms the gate dielectric of the final transistor device 340. The dielectric layer typically has a thickness of the order 100-600 nm. The width of the dielectric layer exceeds the gate width of the transistor device 340, which is typically 1-5 μm.

Anisotropic electrolytic deposition of metal is then carried out. As illustrated in FIG. 4E, a first further metal portion 324a is deposited on the first metal portion 310a and a second further metal portion 324c is deposited on the second metal portion 310c. The combination of the metal portions 310a and 324a forms the drain of the final transistor device 340 and the combination of the metal portions 310c and 324c forms the source of the final transistor device 340. A well or channel 326 is formed above the dielectric 322 and between the first and second further metal portions 324a and 324c. Brightening agents can be added to the electrolytic solution to control the isotropy/anisotropy of metal growth. This can be used to control the cross-sectional profile of the well or channel 326.

In FIG. 4F, semiconductor material 330 is deposited into the well or trench 326 to fill it. The semiconductor may, for example, be an organic semiconductor, a solution processable semiconductor, nano-particulate dispersion of semiconductor; conjugated polymers or oligomers in solution or any other suitable alternative. The semiconductor may be deposited by spinning it on in liquid solvent form and evaporating the solvent. Alternatively micro-dispensing techniques such as piezo inkjet or thermal inkjet may be used to selectively fill the well or trench 326. Further laser, heat or radiation processes may be used to improve the semiconductor properties.

The semiconductor material 330 completes the second layer 318 of the transistor device 340. The second layer 318 includes the further first metal portion 324a, the further third metal portion 324c, the semiconductor material 330 and the dielectric 322. No etch-back or patterning is required to place the semiconductor material in the well or channel 326.

The first and second layers 316 and 318 form a transfer layer which is transferred to a passive substrate 314. The passive substrate 314 is adhered to the substantially planar upper surface of the second layer 318 using a layer of adhesive 312 as illustrated in FIG. 4G. This substrate will form the substrate of the final TFT 340. The substrate 314 may be made of glass. Alternatively, it may be a flexible plastic substrate, for example, made from PET. The adhesive used may be NOA81 by Norland Products Inc. The thickness of the substrate 314 is typically between 50 and 200 um. The thickness of the adhesive layer 312 is typically between 5 and 20 um.

The adhesive layer 312 is cured using ultra-violet (UV) radiation or applied heat. The structure may then be shock-cooled and the passivated conductive carrier 302 is removed (peeled-off) to form the TFT device 340, as illustrated in FIG. 4H. In FIG. 4H, the structure has been inverted.

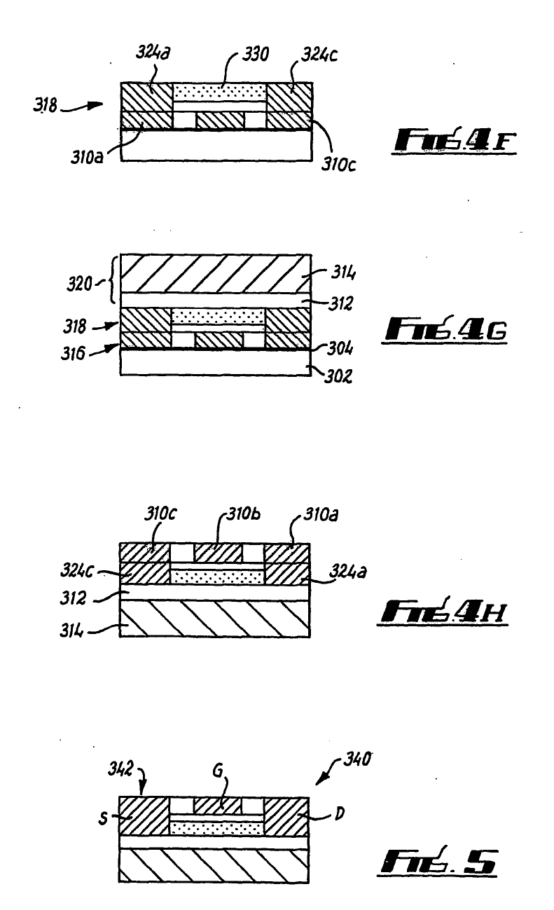

The final TFT device is illustrated in FIG. 5. It has a metallic source electrode S, a metallic drain electrode D and a metallic gate electrode G comprising: a first notional layer 316 including the metallic gate electrode G, a first portion 310c of the metallic source electrode S and a first portion 310a of the metallic drain electrode D; a second notional layer 318 including a second portion 324c of the metallic source electrode, a second portion 324a of the metallic drain electrode and deposited semiconductor material 330 overlying dielectric material 322; and a third layer 320 including a passive substrate 314 and adhesive 312. The join between the first layer 316 and the second layer 318 through the source S and drain D may be discernable. The metal portions 310a, 310b, 310c, 324a and 324c will generally contain artefacts of the electrolytic process by which they were formed. The TFT device 340 has an upper substantially planar surface 342 including the upper substantially planar surfaces of the first, second and third metal portions 210a, 210b and 210c.

The substrate 314 may be a large area flexible substrate (many square centimetres or metres) with thousands or millions of devices 340 integrated thereon. The above-described methods may be applied simultaneously across the whole area to form multiple devices.

It should be appreciated that the above-described method has a number of advantages. The method requires a small number of masks and the associated problem of their accurate alignment is limited. The use of electrolytic deposition of metal on the first and second metal portions to form the relief for receiving the semiconductor 330 is a self-aligning process. The above-described processes can be carried out at low temperature (room temp +/−100 degrees Celsius) and without vacuum processing. There may additionally be no need for further processing on the final substrate 314, which may be flexible plastic for example. The semiconductor material may be encapsulated within the surface of the resulting device, rendering it robust and reducing susceptibility to any contamination/chemical attack from subsequent processing. The resulting upper surface of the device may be substantially planar which is also advantageous for further processing, particularly in display applications.

Although embodiments of the present invention have been described in the preceding paragraphs with reference to various examples, it should be appreciated that modifications to the examples given can be made without departing from the spirit and scope of the invention. For example, referring to FIGS. 4E and 4F, the electro-deposition of metal to form the further first and third metal portions 324a and 324c may occur before or after the deposition of semiconductor material 330.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/we claim:

1. A semiconductor device comprising:
a first electrode component;
a second electrode component;
a first layer comprising at least a portion of the first electrode component and at least a portion of the second electrode component;
a second layer having a portion comprising deposited semiconductor material contacting the first and second electrode components; and
a third layer comprising a substrate,
wherein the first, second and third layers are arranged in order such that the second layer is positioned between the first layer and the third layer and
wherein the first and second electrode components comprise electro-deposited metal.

2-4. (canceled)

5. A semiconductor device as claimed in claim 1, wherein the deposited semiconductor material comprises organic semiconductor material.

6. (canceled)

7. A semiconductor device as claimed in claim 1, wherein the semiconductor material is embedded in the device and overlain by the first layer.

8. A semiconductor device as claimed in claim 1 wherein the substrate is flexible.

9. A semiconductor device as claimed in claim 1, wherein the device is a thin film transistor having a channel in the semiconductor material, a source electrode as the first electrode, a drain electrode as the second electrode, and a gate electrode, wherein the source, drain and gate electrodes are formed from electro-deposited metal

10. A semiconductor device as claimed in claim 9, wherein the first layer comprises the source electrode and the drain electrode and the gate electrode lies in a fourth layer between the second layer and the third layer, the semiconductor device further comprising a fifth layer, comprising a continuous dielectric layer, between the fourth layer and the third layer.

11-13. (canceled)

14. A semiconductor device as claimed in claim 10, wherein the source and drain electrodes each partially overlap the gate electrode but are separated therefrom by the semiconductor material and dielectric material.

15-17. (canceled)

18. A semiconductor device as claimed in claim 9, wherein the first layer comprises a first portion of the source electrode, a first portion of the drain electrode and the gate electrode.

19. A semiconductor device as claimed in claim 18, wherein the second layer comprises a second portion of the source electrode contacting the semiconductor material and a second portion of the drain electrode contacting the semiconductor material.

20-21. (canceled)

22. A semiconductor device as claimed in claim 18, further comprising dielectric material in the second layer between the semiconductor material and the gate electrode in the first layer.

23. A semiconductor device as claimed in claim 18, wherein the first layer has a substantially planar surface forming a surface of the semiconductor device incorporating portions of the source, drain and gate electrodes.

24. A substrate for a display device comprising a plurality of semiconductor devices as claimed in claim 1.

25. A method for use in forming a layered semiconductor device comprising:
forming a transfer layer on a conductive carrier by at least the deposition of insulating material on the conductive carrier and then the electro-deposition of metal onto at least first and second portions of the conductive carrier, selectively exposed through the insulating material, to form first and second metal portions;
fixing the transfer layer to a substrate portion of the device; and
removing the conductive carrier from the device.

26-28. (canceled)

29. A method as claimed in claim 25, wherein the step of fixing the transfer layer to a substrate portion embeds semiconductor material within the device.

30. (canceled)

31. A method as claimed in claim 25, wherein the formation of the substrate portion comprises:
forming a gate transfer layer on a second conductive carrier by depositing insulating material on the second conductive carrier and then electro-depositing metal onto a portion of the second conductive carrier, selectively exposed through the insulating material;
fixing the gate transfer layer to a substrate; and
removing the conductive carrier from the device.

32-34. (canceled)

35. A method as claimed in claim 31, further comprising forming a dielectric layer over the gate transfer layer after it is fixed to the substrate.

36. A method as claimed in claim 35, further comprising depositing an adhesive insulating layer over the dielectric layer and selectively removing the adhesive insulating layer from over the gate electrode to form a well.

37-41. (canceled)

42. A method as claimed in claim 25, wherein the transfer layer is formed by:
a) selectively forming insulating material on portions of the conductive carrier, to expose first, second and third portions of the conductive carrier;
b) electro-depositing metal onto the first, second and third portions of the conductive carrier to form first, second and third metal portions;
c) depositing dielectric material over at least the second metal portion;
d) electro depositing metal on the first and third metal portions; and
e) depositing semiconductor material over the dielectric layer.

43. (canceled)

44. A method as claimed in claim 42, wherein the step e) precedes step d).

45-48. (canceled)

49. A method for use in forming a transistor device including a source electrode, a drain electrode and a gate electrode comprising:
electro-depositing metal to form at least a portion of the gate electrode;
electro-depositing metal to form simultaneously at least portions of the source electrode and the drain electrode;
depositing semiconductor material;
transferring at least the source electrode and drain electrode to a substrate.

50-58. (canceled)
